(19) United States
(12) Patent Application Publication
(10) Pub. No.: US 2006/0065937 A1
(43) Pub. Date: Mar. 30, 2006

(54) Short channel effect of MOS devices by retrograde well engineering using tilted dopant implantation into recessed source/drain regions

(76) Inventors: Thomas Hoffmann, Portland, OR (US); Sunit Tyagi, Portland, OR (US); Giuseppe Curello, Portland, OR (US); Berhard Sell, Portland, OR (US); Christopher Auth, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/954,914

(22) Filed: Sep. 30, 2004

(51) Int. Cl. H01L 29/76; H01L 21/336

(52) U.S. Cl. 257/401; 438/284

(57) ABSTRACT

A method of providing a halo implant region in a substrate of a MOS device having a gate electrode thereon and defining source/drain regions, a MOS device fabricated according to the above method, and a system comprising the MOS device. The method comprises: defining undercut recesses in the substrate at the source/drain regions thereof, the undercut recesses extending beneath the gate electrode; creating a halo implant region beneath the gate electrode between the recesses; and providing raised source/drain structures in the undercut recesses after creating the halo implant region.

### FIELD

Embodiments of the present invention relate to the manufacture of semiconductor devices, and, in particular, to methods of improving short channel effects in MOS devices, and to MOS devices made according to such methods.

### BACKGROUND

Conventionally, the reduction of undesirable short channel effects in MOS devices has been accomplished by using halo implantation to increase the amount of doping in the MOS wells in order to sustain smaller gate length when the device is in operation. Halo implantation leads to a non-uniform doping of the well, that is, to higher doping around the edges of the MOS gate. Halo implantation will reinforce the well concentration, in this way displacing the source/well and drain/well junction far away with respect to the edges of the gate, thus allowing a more ready control of the leakage current when the gate length is reduced. A disadvantage of prior art methods involving halo implantation is that they lead to a degradation in the mobility of carriers, and consequently of the drive current of the MOS device.

### BRIEF DESCRIPTION OF THE DRAWINGS

Embodiments of the present invention are illustrated by way of example and not by way of limitation in the figures of the accompanying drawings, in which like references indicate similar elements, and in which:

FIG. 1a is a schematic cross-sectional side-elevational view of a transistor structure partially fabricated based on standard CMOS flow up to spacer formation;

FIG. 1b is a schematic cross-sectional side-elevational view of the partially fabricated transistor structure of FIG. 1a, exhibiting undercut recesses according to an embodiment of the present invention;

FIG. 1c is a schematic cross-sectional side-elevational view of the partially fabricated transistor structure of FIG. 1b, showing the structure as undergoing tilt-angle implantation according to an embodiment of the present invention;

FIG. 1d a schematic cross-sectional side-elevational view of the partially fabricated transistor structure of FIG. 1c, exhibiting a halo implant region underneath the gate electrode of the partially fabricated transistor structure according to an embodiment of the present invention;

FIG. 2 is a flow diagram of a method of providing a retrograde well profile in a MOS device according to an embodiment of the present invention;

FIG. 3a a schematic cross-sectional side-elevational view of a portion of partially fabricated transistor structure exhibiting an undercut recess and prior to tilt-angle implantation according to an embodiment of the present invention;

FIG. 3b a schematic cross-sectional side-elevational view of the portion of the partially fabricated transistor structure of FIG. 3a, exhibiting a retrograde well profile according to an embodiment of the present invention;

FIG. 4 is a graph plotting dopant concentration versus depth before and after tilt-angle implantation for the partially fabricated transistor structure of FIGS. 3a and 3b;

FIG. 5 is a graph plotting threshold voltage versus gate length for a given leakage target for a MOS device of the prior art and for a MOS device fabricated according to an embodiment of the present invention; and

FIG. 6 is a schematic diagram depicting a system incorporating a MOS device fabricated according to embodiments of the present invention.

### DETAILED DESCRIPTION

A method of providing a halo implant region in a MOS device, a MOS device exhibiting a halo implant region, and a system incorporating a MOS device exhibiting a halo implant region are disclosed herein. Embodiments of the present invention advantageously allow the fabrication of MOS devices, such as, for example, sub 100 nanometer MOS devices, which exhibit improved short channel effects as compared with MOS devices of the prior art.

Various aspects of the illustrative embodiments will be described using terms commonly employed by those skilled in the art to convey the substance of their work to others skilled in the art. However, it will be apparent to those skilled in the art that embodiments of the present invention may be practiced with only some of the described aspects. For purposes of explanation, specific numbers and configurations are set forth in order to provide a thorough understanding of the illustrative embodiments. However, it will be apparent to one skilled in the art that embodiments the present invention may be practiced without the specific details provided herein. In other instances, well-known features are omitted or simplified in order not to obscure the illustrative embodiments.

Various operations will be described as multiple discrete operations, in turn, in a manner that is most helpful in understanding embodiments of the present invention, however, the order of description should not be construed as to imply that these operations are necessarily order dependent. In particular, these operations need not be performed in the order of presentation.

The phrase “embodiment” is used repeatedly. The phrase generally does not refer to the same embodiment, however, it may. The terms “comprising”, “having” and “including” are synonymous, unless the context dictates otherwise.

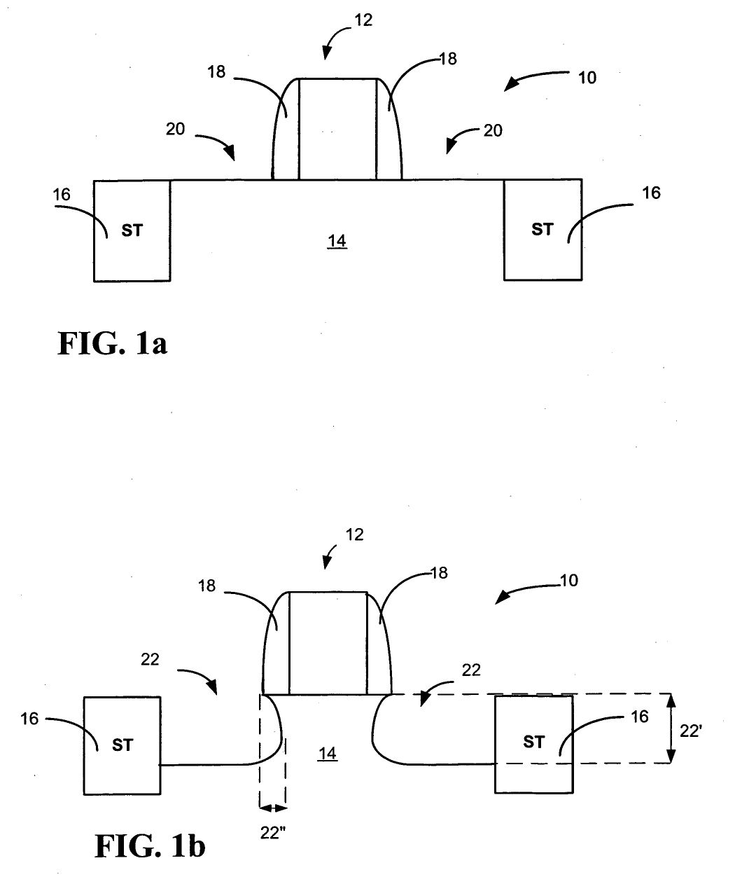

FIGS. 1a-1d illustrate, by way of example, transistor structures in various stages of fabrication of a MOS device according to an embodiment of the present invention.

A partially fabricated transistor structure 10 is shown in an initial stage of fabrication at FIG. 1a, where transistor structure 10 includes a gate electrode 12 disposed on surface of a semiconductor substrate 14 in which shallow isolation trenches 16 marked “ST” on the figures have been created. By “partially fabricated transistor structure,” what is meant in the context of the present description is a transistor structure in an intermediate stage of fabrication having at least a gate electrode, including gate electrode spacers, having a substrate doped to define either an n-well or a p-well disposed beneath the gate electrode, and source/drain extensions. Referring back to FIG. 1a, Source/Drain or S/D regions 20 are provided on the substrate at each side of the gate electrode 12. The S/D regions correspond to regions where raised S/D structures are to be eventually deposited. Substrate 14 may be part of a test chip on a starting p-type Si substrate where the MOS device being fabricated is a PMOS device, or on a starting n-type Si substrate where the MOS device being fabricated is an NMOS device. FIG. 1a shows partially fabricated transistor structure 10 after standard CMOS flow through the definition of spacers 18.

Referring next to FIG. 1b, partially fabricated transistor structure 10 is shown at an intermediate stage of fabrication according to embodiments of the present invention, in which S/D regions 20 previously shown in FIG. 1a have been selectively removed, as would be within the knowledge of a person skilled in the art. A key feature according to embodiments of the present invention is to extend the etched regions close enough to the edge of the gate, so that a lower energy can be used to implant the dopant beneath the channel in order to obtain a retrograde well. The selective removal of S/D regions 20 results in the formation of undercut recesses 22. In the instant description, an “undercut recess” refers to a recess that extends both in a direction orthogonal to a surface of the substrate (corresponding to a depth of the recess), and, in addition, in a direction parallel to a surface of the substrate and extending beneath the spacers (corresponding to an extent of undercut of the recess). According to embodiments of the present invention, the extent of selective removal of the S/D regions may correspond to: a removal depth 22′ ranging from about 10 nm to about 150 nm, and preferably from about 60 nm to about 90 nm and an extent of undercut 22″ ranging from about 0 to about 40 nm and preferably from about 20 nm to about 25 nm. According to embodiments of the present invention, it is not necessary for the recesses to define the shapes shown in the exemplary FIGS. 1b-1d. Embodiments of the present invention encompass within their scope the formation of recesses of any shape defining a depth and an extent of undercut as defined above. Preferably, according to embodiments of the present invention, selective removal of S/D regions 20 takes place by using any of well known etching techniques, such as, for example, SF6, NF3, C12, wet etches or other types of etching techniques as would be within the knowledge of a person skilled in the art. The choice between different conventional etch techniques would be dictated by the desired shape of the recess, and would thus impact, but only to a small extent, MOS performance, to the extent that the shape of the recess would modulate how the dopants of the tilted implant would distribute into the silicon.

As depicted in FIG. 1c, partially fabricated transistor structure 10 is shown at a subsequent, intermediate stage of fabrication according to embodiments of the present invention. In particular, FIG. 1c shows a tilt-angle implantation 24 of dopants of the same type as dopants of the well (i.e. n-type or p-type) toward recesses 22 to form a localized halo implant region 26 beneath the gate electrode between the recesses 22. By “beneath the gate electrode,” what is meant in the context of embodiments of the present invention is a location that is at least partially beneath the gate electrode. By “between the recesses,” what is meant in the context of embodiments of the present invention is a location that is at least partially between the recesses. Tilt-angle implantation 24 according to embodiments of the present invention may be performed using conventional tilt-angle implantation techniques. Furthermore, according to embodiments of the present invention, a range of tilt angles α (measured with respect to an axis orthogonal to the surface of the substrate, and depicted as a doted line Z-Z in FIG. 1c) suitable for tilt-angle implantation may include angles between about 20 degrees and about 50 degrees and, preferably, angles between about 30 degrees and about 40 degrees. The dopants used for tilt-angle implantation according to embodiments of the present invention may include, by way of example, n-type dopants such as arsenic, phosphorus or antimony, or p-type dopants such as boron or indium as a function of the type of MOS device being fabricated. According to embodiments of the present invention, species used in tilt-angle implantation 24 may be the same as the dopants used to implant the wells of the transistor device 10, or, in the alternative, they may include other species, such as, by way of example, Ge, F or C. Ge, F and C are in column IV of the periodic table, and, as such, do not lead to a doping of the wells. However, Ge, F and C are known to suppress the diffusion of other species, such as boron or phosphorus into the silicon from the raised S/D regions. Thus, Ge, F and C, or similar species, may be used according to an embodiment of the present invention to prevent the species implants of the S/D regions to overrun the device. That is, Ge, F, C or similar species prevent the dopants of the S/D regions to diffuse to the extent that they would push the S/well and D/well junction to regions far toward the middle portion of the device. According to one embodiment, halo implant region 26 may be formed by way of tilt-angle implantation with dopant doses ranging from about 1×10¹³ atoms/cm³ to about 5×10¹⁴ atoms/cm³, and preferably from about 2×10¹³ atoms/cm³ to about 5×10¹³ atoms/cm³. The halo implant region 26 is implanted at a predetermined depth of interest 26′ below the gate electrode 12. The depth of interest 26′, according to embodiments of the present invention, may be between about 10 nm to about 60 nm, and may further achieved using an implantation energy ranging from about 5 keV to about 60 keV. For the tilt-angle implantation according to embodiments of the present invention, it must be kept in mind that if the tilt angle is large (for example, above about 40 degrees), and the spacing between adjacent components of the MOS device is small, (for example, about 100 nm), there might some shadowing issue from the gates.

Referring next to FIG. 1d, according to embodiments of the present invention, raised S/D structures 30 are formed in the recesses 22 to a depth of 30′ and to a height of 30″, substantially filling the recesses 22. According to embodiments of the present invention, the thickness of the raised S/D structures, that is, the sum of depth 30′ and height 30″, may range from about 40 nm to about 300 nm. The raised S/D structures may be formed using any of the well known techniques in the art, such as, for example through the selective epitaxial growth. Epitaxial deposition may, in accordance with an embodiment of the invention, be a low temperature selective epitaxial deposition LT-SE of in-situ doped silicon, such as for example Si/SiGe and Boron, or Si/SiGe and As, to provide in-situ doped S/D structures 30 as shown. Halo implant region 26 can advantageously suppress the diffusion of the dopant in the raised S/D structures 30 into the substrate.

After formation of the S/D structures 30 as shown by way of example in FIG. 1d, standard CMOS flow may be used in order to complete fabrication of a MOS device according to embodiments of the present invention.

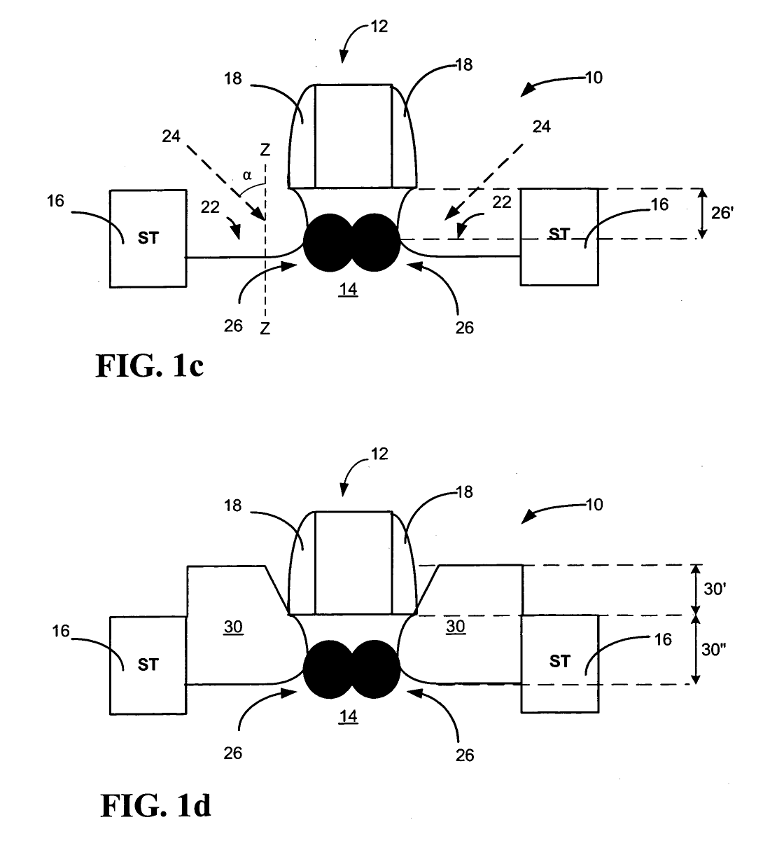

FIG. 2 illustrates, by way of example, a flow diagram of a method of providing a MOS device having a retrograde well profile according to embodiments of the present invention. At 1001, the method includes defining undercut recesses in the substrate by removing S/D regions from a substrate of a partially fabricated transistor structure. At 1002, the method includes providing halo implant region beneath the gate electrode by tilt-angle implanting dopants directed toward undercut portions of the recesses. At 1003, the method includes providing raised source/drain structures in the undercut recesses. Embodiments of the method according to FIG. 2 may be employed by way of example to form corresponding stages of the partially fabricated transistor structures shown in FIGS. 1a-1d, other configurations of partially fabricated transistor structures being within the realm of embodiments of the present invention. Thus, 1001 could, by way of example, result in the profile shown in FIG. 1b; 1002 could, by way of example, result in the profile shown in FIG. 1c; and 1003 could, by way of example, result in the profile shown in FIG. 1d, other profiles being within the scope of the present invention as readily recognizable by one skilled in the art.

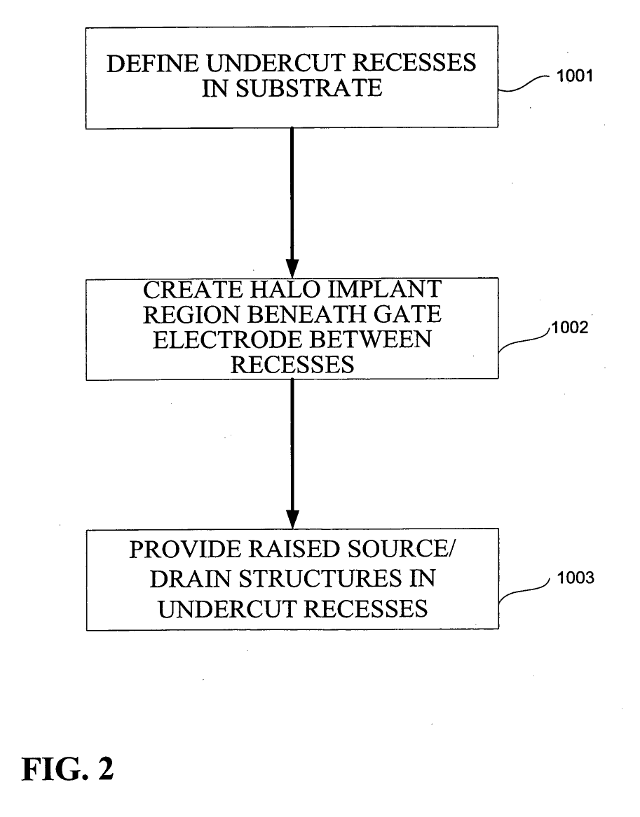

Referring next to FIGS. 3a and 3b, a cross sectional profile obtained by simulation of a portion 200 of a partially fabricated transistor structure 210 after spacer definition is shown according to an embodiment of the present invention. The X and Y axes correspond to dimensions in microns along the length and height (or depth) of the shown portion 200. Portion 200 includes a portion of a gate electrode 212 including one of two spacers 218. One of two undercut recesses 222 is also prominently shown. A dopant concentration legend bar 232 is provided on the right of portion 200.

Referring to FIG. 3a, the partially fabricated transistor structure 210 in that figure is at the same stage of its fabrication as, for example, partially fabricated transistor structure 10 shown in FIG. 1b and described above. Legend bar 232 at the right of FIG. 3a allows an evaluation of a distribution of dopants already present in bulk regions 234 of portion 200 and in parts of the gate electrode 212, the concentration of dopants in bulk regions 234 shown in FIG. 3a representing the already doped well regions of the portion 200.

Referring next to FIG. 3b, portion 200 of partially fabricated transistor structure 210 previously shown in FIG. 3a is depicted after tilt-angle implantation according to an embodiment of the present invention. The partially fabricated transistor structure 210 in FIG. 3b is at the same stage of its fabrication as, for example, partially fabricated transistor structure 10 shown in FIG. 1c and described above. As shown in FIG. 3b, tilt-angle implantation as depicted by the three bold arrows in FIG. 3b is directed toward the undercut recess 222, while the spacers about the gate electrode serve as a mask that prevent the dopant from directly reaching the channel. The tilt-angle implantation shown occurs at an angle of about 40 degrees and results in the formation of halo implant region 226 beneath the gate electrode 212 as shown. In the shown figures, because of the relatively small size of the gate, the halo regions from the S and D sides have merged together and resulted in a peak halo concentration in the middle of the device. Advantageously, most of the dopants of the tilt-angle implantation do not penetrate into the channel region, such that there is a substantial improvement in the surface properties of a MOS device formed from the partially fabricated transistor structure 210, such as threshold voltage, which increases at a much smaller rate as compared with the prior art. Implanted dopants not screened by the spacer significantly reinforce dopant concentrations in the well deeper into the bulk regions of the substrate.

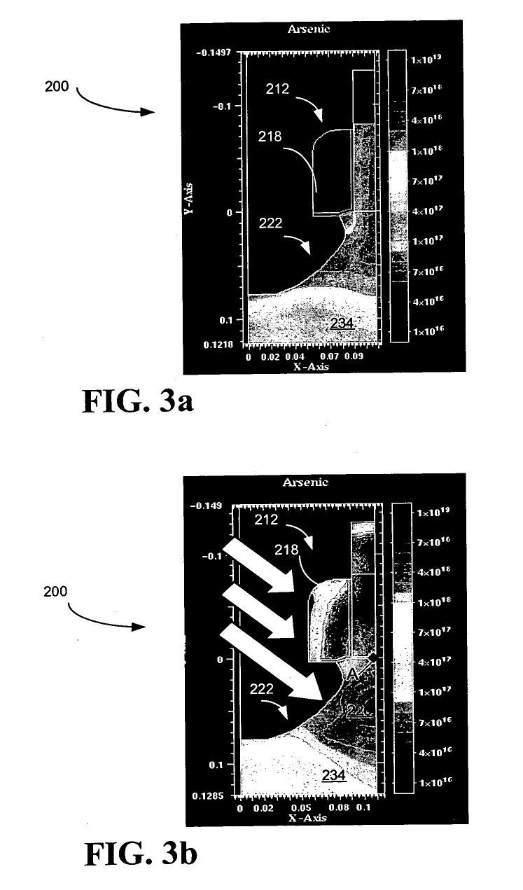

Referring next to FIG. 4, a graph of dopant concentration versus depth is shown for the partially fabricated transistor structure 200 of FIG. 3b. In FIG. 4, dopant concentrations are plotted at a depth starting slightly above point A in FIG. 4, and along a cut-line extending toward the well and away from the gate electrode in the direction of the Y axis. Point A corresponds to zero depth at the substrate/gate electrode interface at a central portion of the gate electrode, and the cut-line used to generate FIG. 4 starts at about 0.101413 micron above point A as stated on the graph of FIG. 4. As shown clearly in FIG. 4, a MOS device fabricated according to the embodiment of the present invention shown in FIGS. 3a and 3b exhibits higher dopant concentrations overall along a depth of the MOS well, and a higher peak concentration corresponding to a halo implant or retrograde well region, advantageously resulting in an improved retrograde well profile, and thus in improved short-channel effects of the results MOS device.

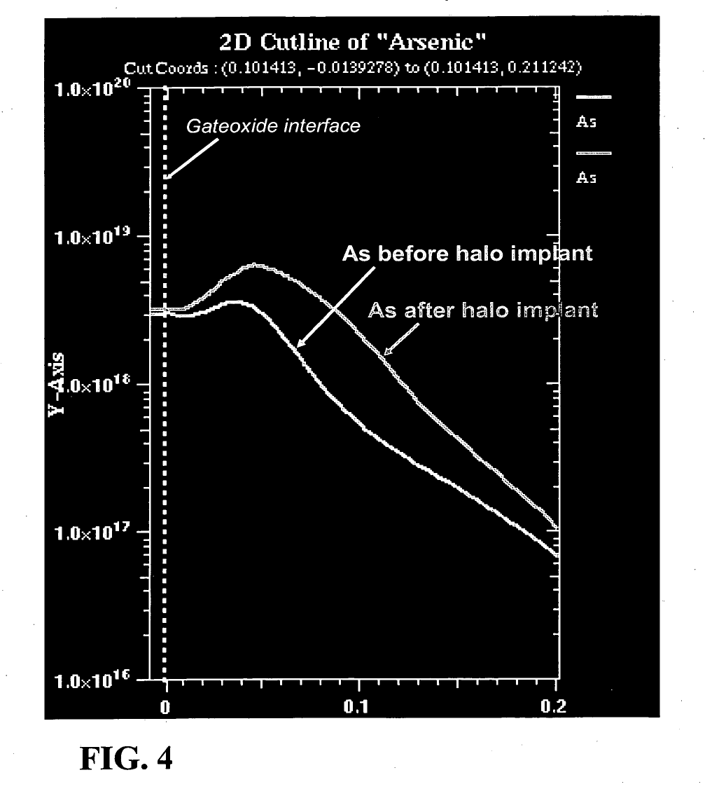

FIG. 5 is a graph of threshold voltage VTP in Volts plotted versus gate length FCCD in nanometers for a given leakage target (as indicated by “@opt” in FIG. 5) between about 100 to about 200 nA/μm (the leakage target having been normalized per unit width in a direction perpendicular to the views shown of the MOS devices depicted herein) for a MOS device fabricated according to an embodiment of the present invention. As suggested in FIG. 5, for the embodiments of the present invention that would yield the VTP versus FCCD curve shown in the figure, and for a given leakage target, at the same VTP, gate lengths are appreciably smaller. By way of example, for a VTP of about 0.45 Volts, embodiments of the present invention can support a gate length that is about 2 nanometers smaller than a gate length of an otherwise identical MOS device not including a retrograde well profile according to embodiments of the present invention. As mentioned previously, smaller gate lengths are advantageously possible according to embodiments of the present invention by virtue of deeper subsurface doping of MOS wells resulting from halo implantation.

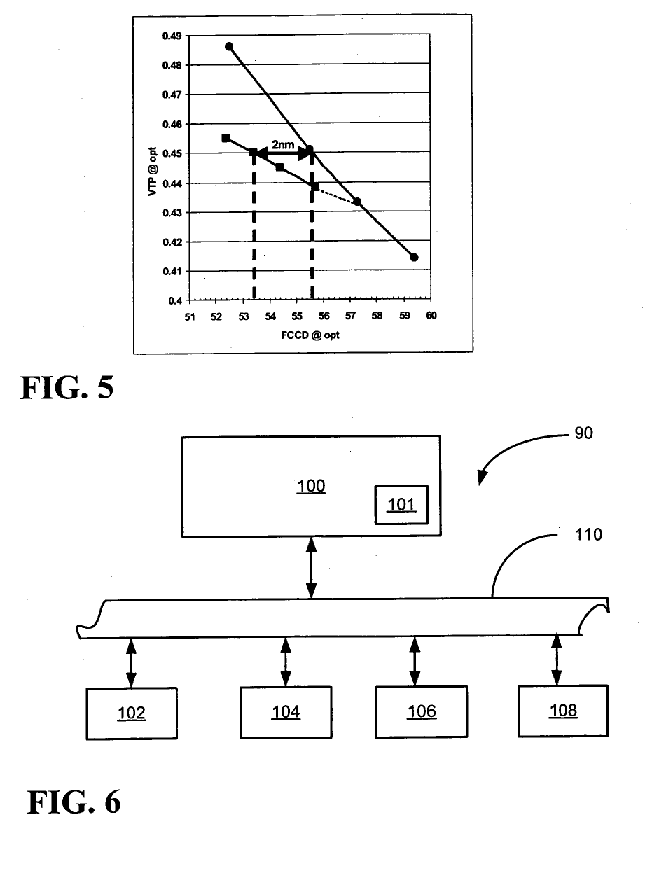

Referring to FIG. 6, there is illustrated one of many possible systems 90 in which a MOS device 101 formed according to embodiments of the present invention may be used. In one embodiment, the electronic assembly 100 may include a microprocessor. In an alternate embodiment, the electronic assembly 100 may include an application specific IC (ASIC). Integrated circuits found in chipsets (e.g., graphics, sound, and control chipsets) may also be packaged in accordance with embodiments of this invention.

For the embodiment depicted by FIG. 6, the system 90 may also include a main memory 102, a graphics processor 104, a mass storage device 106, and/or an input/output module 108 coupled to each other by way of a bus 110, as shown. Examples of the memory 102 include but are not limited to static random access memory (SRAM) and dynamic random access memory (DRAM). Examples of the mass storage device 106 include but are not limited to a hard disk drive, a compact disk drive (CD), a digital versatile disk drive (DVD), and so forth. Examples of the input/output module 108 include but are not limited to a keyboard, cursor control arrangements, a display, a network interface, and so forth. Examples of the bus 110 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

Advantageously, tilt-angle implantation according to embodiments of the present invention results in the formation of retrograde well profiles at the halo implant region 26, that is, results in the formation of higher well dopant concentrations in the bulk regions of the transistor structure 10 than in the channel region of the same. Typical well dopant concentrations achieved by embodiments of the present invention are from about 1×10¹⁸ atoms/cm³ to about 1×10¹⁹ atoms/cm³. The above concentrations may be achieved according to embodiments of the present invention using input doses ranging from about 1×10¹³ atoms/cm² to about 1×10¹⁴ atoms/cm².

At least two main advantages are realized by the formation of retrograde well profiles according to embodiments of the present invention. First, such retrograde well profiles allow for better short channel effect control, allowing the gate length to be scaled while maintaining the same off-state current leakage and threshold voltage (VT). Second, retrograde well profiles according to embodiments of the present invention, by virtue of the gate length scaling, advantageously allow for better drive current at a given VT, meaning that the same doping level in the channel will not lead to degradation in mobility within the device. Additionally, embodiments of the present invention allow for minimum changes to be made to well known baseline MOS fabrication processes while providing the advantages notes above.

According to embodiments of the present invention, a key advantage is that the need to use large amounts of energy for dopant implantation beneath the channel region is obviated by virtue of performing the tilted implantation after etching the recesses. As a result, the spacer adjacent to the gate is able to screen implanted dopants efficiently. If no etching is performed before dopant implantation, the large energy required to implant dopants beneath the channel region would tend to further implant dopants, in significant amounts, not only in the spacer but also in the channel, in this way reducing the retrograde profile of the well. In addition, a fill back of the recesses with a large volume of low resistive material, such as, for example, epitaxial material, according to embodiments of the present invention, advantageously allows the current to spread easily before entering the contacts of the MOS device.

Although the instant description pertains in general to elevated raised source/drain devices, embodiments of the present invention encompass within their scope the extension of tilted implantation to cases without raised source/drain regions. In such cases, the contacts to the source and drain would be directly formed into the recessed regions of the MOS device.

Additionally, embodiments of the present invention encompass within their scope tilted implantation on only one side of a MOS gate, and, therefore, an asymmetric doping, such that either the source or the drain will receive more dopants than the other. Embodiments of the present invention further encompass within their scope the performance of an additional implant after the removal of source/drain regions using dopants of the same type as the source/drain regions as a compensation implant. A function of a compensation implant would be to reduce a parasitic capacitance of the MOS device being fabricated. In addition, according to embodiments of the present invention, it would be possible to effect multiple implantations of dopants and/or of neutral species such as, for example, Ge, F or C after source/drain removal using different tilt/energy/doses for each implantation or order to further optimize the gain of a MOS device fabricated as a result.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A method of providing a halo implant region in a substrate of a MOS device having a gate electrode thereon and defining source/drain regions, the method comprising:
defining undercut recesses in the substrate at the source/drain regions thereof, the undercut recesses extending beneath the gate electrode;
creating a halo implant region beneath the gate electrode between the recesses; and
providing raised source/drain structures in the undercut recesses after creating the halo implant region.

2. The method of claim 1, wherein defining undercut recesses comprises etching the substrate at the source/drain regions.

3. The method of claim 1, wherein the undercut recesses have a depth ranging from about 10 nm to about 50 nm.

4. The method of claim 1, wherein the undercut recesses have a depth ranging from about 60 nm to about 90 nm.

5. The method of claim 1, wherein an extent of undercut of the undercut recesses ranges from about 0 nm to about 40 nm.

6. The method of claim 5, wherein an extent of undercut of the undercut recesses ranges from about 20 nm to about 25 nm.

7. The method of claim 1, wherein creating the halo implant region comprises effecting tilt-angle implantation of dopants directed toward the recesses.

8. The method of claim 7, wherein effecting tilt-angle implantation comprises tilt-angle implanting at an angle ranging from about 20 degrees to about 50 degrees.

9. The method of claim 8, wherein effecting tilt-angle implantation comprises tilt-angle implanting at an angle ranging from about 30 degrees to about 40 degrees.

10. The method of claim 7, wherein tilt-angle implantation comprises tilt-angle implanting at an implantation energy level between about 5 KeV to about 60 KeV.

11. The method of claim 7, wherein effecting tilt-angle implantation comprises tilt-angle implanting n-type dopants selected from the group consisting of arsenic, phosphorus and antimony, or p-type dopants selected from the group consisting of as boron and indium.

12. The method of claim 7, wherein effecting tilt-angle implantation comprises tilt-angle implanting dopants in concentrations ranging from 1×10¹³ atoms/cm³ to about 5×10¹⁴ atoms/cm³.

13. The method of claim 7, wherein effecting tilt-angle implantation comprises tilt-angle implanting dopants in concentrations ranging from about 2×10¹³ atoms/cm³ to about 5×10¹³ atoms/cm³.

14. The method of claim 7, wherein effecting tilt-angle implantation comprises tilt-angle implanting dopants identical to dopants used to create a well of the MOS device.

15. The method of claim 1, wherein providing raised source/drain structures comprises effecting epitaxial deposition of the raised source/drain structures.

16. The method of claim 15, wherein effecting epitaxial deposition comprises effecting a low temperature selective epitaxial deposition of selectively doped silicon to provide in-situ doped raised source/drain structures.

17. A method of providing a MOS device, comprising:
providing a partially fabricated transistor structure including a substrate and a gate electrode disposed on the substrate;
defining undercut recesses in the substrate at the source/drain regions thereof, the undercut recesses extending beneath the gate electrode;
creating a halo implant region beneath the gate electrode between the recesses;
providing raised source/drain structures in the undercut recesses after creating the halo implant region; and
utilizing CMOS flow to complete fabrication of the MOS device after providing raised source/drain structures.

18. The method of claim 17, wherein defining undercut recesses comprises etching the substrate at the source/drain regions.

19. The method of claim 17, wherein creating the halo implant region comprises effecting tilt-angle implantation of dopants directed toward the recesses.

20. The method of claim 17, wherein providing raised source/drain structures comprises effecting epitaxial deposition of the raised source/drain structures.

21. The method of claim 20, wherein effecting epitaxial deposition comprises effecting a low temperature selective epitaxial deposition of selectively doped silicon to provide in-situ doped raised source/drain structures.

22. A MOS device comprising:
a semiconductor substrate;
a gate electrode disposed on the semiconductor substrate, the semiconductor substrate further defining undercut recesses extending beneath the gate electrode at each side of the gate electrode;
a halo implant region disposed beneath the gate electrode between the recesses; and
raised source/drain structures disposed in the recesses at each side of the gate electrode.

23. The MOS device of claim 22, wherein the undercut recesses have a depth ranging from about 10 nm to about 50 nm.

24. The MOS device of claim 22, wherein an extent of undercut of the undercut recesses ranges from about 0 nm to about 40 nm.

25. The MOS device of claim 22, wherein a dopant concentration of the halo implant region ranges from about 1×10¹⁸ atoms/cm³ to about 1×10¹⁹ atoms/cm³.

26. The MOS device of claim 22, wherein dopants in the halo implant region are n-type dopants selected from the group consisting of arsenic, phosphorus and antimony, or p-type dopants selected from the group consisting of as boron and indium.

27. The MOS device of claim 22, wherein dopants in the halo implant region are dopants of species identical to dopants used to create a well of the MOS device.

28. A system comprising:
an electronic assembly including an integrated circuit having a MOS device, the MOS device comprising:
a semiconductor substrate;
a gate electrode disposed on the semiconductor substrate, the semiconductor substrate further defining undercut recesses extending beneath the gate electrode at each side of the gate electrode;
a halo implant region disposed beneath the gate electrode between the recesses; and
raised source/drain structures disposed in the recesses at each side of the gate electrode; and
a graphics processor coupled to the electronic assembly.

29. The system of claim 28, wherein the raised source/drain structure are epitaxial structures.
